(19) United States
(12) Patent Application Publication
(10) Pub. No.: US 2008/0082877 A1
(43) Pub. Date: Apr. 3, 2008

(54) Integrated testing system for wireless and high frequency products and a testing method thereof

(76) Inventors: Ho-Cheng Hung, Tsao Tuen (TW); Kun-Lin Tsai, Tsao Tuen (TW); Po-Liang Lin, Tsao Tuen (TW); Chun-Ming Wu, Tsao Tuen (TW); Yi-Cheng Hung, Tsao Tuen (TW); Yu-Ta Chu, Tsao Tuen (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/522,366

(22) Filed: Sep. 18, 2006

(51) Int. Cl. G01R 31/28

(52) U.S. Cl. 714/724

(57) ABSTRACT

A testing system selects one of testing paths based on a control unit and a test switching unit for randomly executing tests upon a plurality of products based on the testing requirements of each of examining units, so as to decrease the costs of equipment, interference between the tests on several products, the idle time of a testing devise and the testing period for tested products.

### BACKGROUND OF THE INVENTION

1. Field of the Invention

The present invention relates to a testing system for digital display screens, and more particularly to a wireless and high frequency product integrated testing system for measuring products according to the testing requirements thereof.

2. Description of the Prior Art

In the current era, the market demands not only that products have to enter the market quickly, but also that they have a certain standard of quality. Therefore, a fast testing procedure and testing accuracy are important points for ensuring the quality of products and satisfying users' testing requirements.

In previous testing methods for wireless and high frequency products, a testing device that measured the various functions of a product, was placed upon the test workbench for each product so as to measure each product one-on-one. In the first of these prior art testing methods, the method reduced interference in the testing period and increased the accuracy and stability of measuring signals when measuring various wireless and high frequency products. However, this method required a large amount of equipment and maintenance costs for the above-described analyzers increase the cost of testing products.

In order to solve the problem of such high testing costs, an integrated testing system was recently developed that uses only a single analyzer and at most two testing workbenches that have can operate on a one-on-one basis and can operate continuously. Thereby, testing can be performed so as to reduce testing costs and shorten the length of time required for testing products. In the second of the prior art testing methods, the integrated testing system had to complete measuring all functions of a product upon a first workbench so that it could move to measuring each function of the next product upon the next workbench.

However, the second testing method merely reduces the period required for placing products into corresponding workbenches. However, the idle periods of analyzers remain unchanged. Furthermore, the measurable ability of an analyzer has a great effect upon both the cost of the equipment and the maintenance costs. That is, the more measurable functions an analyzer has, the greater the cost of equipment and maintenance will be. Hence, the second case reduces the measurable functions of the analyzer so as to reduce both testing costs and testing times. However, the idle period remains unchanged. Subsequently, the quality of tested products is also reduced.

### SUMMARY OF THE INVENTION

It is the object of the present invention to reduce the cost of many analyzers and their subsequent maintenance costs for those same analyzers.

It is another object of the present invention that each examining unit can measure the multiple functions of a product.

It is another object of the present invention to measure various functions of each of the products by time-division multiplexing.

It is another object of the present invention to avoid interference from measuring wireless and high frequency products so as to increase the testing accuracy via a test switching unit that is capable of switching testing paths.

It is another object of the present invention that the integrated testing system measures products based on the testing requirements of each of the examining units. Hence, the present invention can reduce the idle period and the average testing period.

In order to achieve the above objects, the present invention provides an integrated testing system that includes a control unit, a plurality of examining units, an analyzer and a test switching unit, to measure a product in a corresponding examining unit based on the testing requirements thereof. First, the control unit determines whether one of the examining units outputs a testing signal according to the testing requirements thereof. Next, the control unit executes a testing program so as to produce a corresponding control signal based on the testing signal. The test switching unit opens a corresponding testing path from various testing paths based on the control signal. Finally, the analyzer can measure the product in the corresponding examining unit through the opened testing path.

### BRIEF DESCRIPTION OF THE DRAWINGS

The above and further advantages of this invention may be better understood by referring to the following description, taken in conjunction with the accompanying drawings, in which:

FIG. 1 is a block diagram that illustrates the integrated testing system of the present invention;

FIG. 2 is a block diagram that illustrates the control unit controlling the analyzer and test switching unit in the present invention; and

FIG. 3 is a flowchart that illustrates the integrated testing method of the present invention.

The drawings will be described further in connection with the following detailed description of the present invention.

### DETAILED DESCRIPTION OF THE PREFERRED EMBODIMENTS

The integrated testing method of the present invention supports testing separate equipment controls and various chipset controls via a protocol applied to all workbenches for testing products, and is especially applicable for testing wireless and high frequency products.

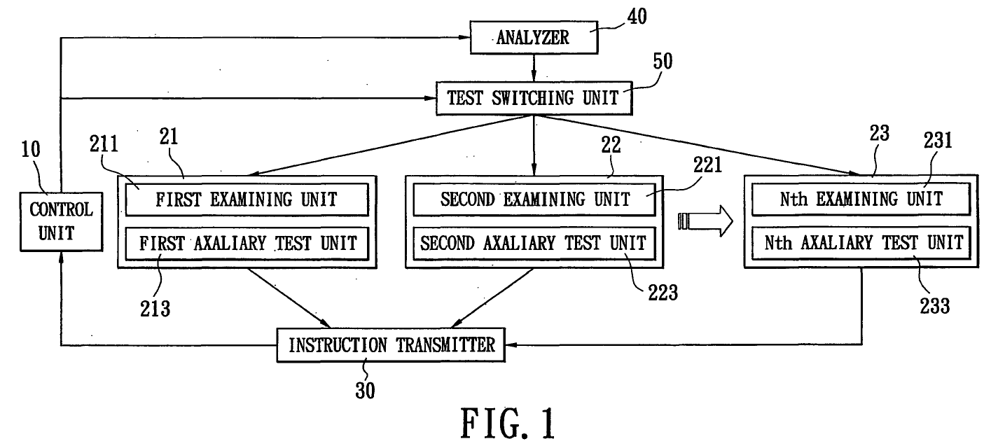

Referring to FIG. 1, an integrated testing system of the present invention is shown. The integrated testing system includes a control unit 10, a plurality of examining units, an instruction transmitter 30, an analyzer 40 and a test switching unit 50, wherein the examining units are respectively include the first examining unit 21 to the Nth examining unit 23.

Each of the examining units includes an examining device and an auxiliary testing unit. That is, the first examining unit 21 includes a first examining device 211 and a first auxiliary testing unit 213, the second examining unit 22 includes a second examining device 221 and a second auxiliary testing unit 223, and the Nth examining unit 23 includes a Nth examining device 231 and a Nth auxiliary testing unit 233. All of above examining devices, from the first examining device 211 to the Nth examining device 231, are what products are placed in for measuring products. All of above auxiliary testing units, from the first auxiliary testing unit 213 to the Nth auxiliary testing unit 233, are computers, and each of the auxiliary testing units connect to a corresponding examining device.

In this case, if a product in the first examining device 211 has to be measured, the first examining device 211 will output a testing signal to the control unit 10 via the first auxiliary testing unit 213. If a product in the second examining device 221 has to be measured, the second examining device 221 will output a testing signal to the control unit 10 via the second auxiliary testing unit 223. Furthermore, if a product in the Nth examining device 231 has to be measured, the Nth examining device 231 will output a testing signal to the control unit 10 via the Nth auxiliary testing unit 233.

Alternatively, the control unit 10 connects to each of the examining units, from the first examining unit 21 to the Nth examining unit 23, via the instruction transmitter 30 and the network. The analyzer 40 connects to the control unit 10 and the test switching unit 50, wherein the instruction transmitter 30 can be a hub, and the analyzer 40 can be a tester, such as a one-box tester(OBT), an Agilent N4010A or an ACE IQ View/Flex and so on. The test switching unit 50 connects to the control unit 10 and each of the examining units.

The control unit 10 executes a testing program according to a testing signal outputted by each of the examining units, for further respectively producing a control signal. Hence, the control unit 10 can control the analyzer 40 and test switching unit 50 via the control signal, wherein the control unit 10 can be a computer. The control unit 10 controls the analyzer 40 to measure randomly each of the examining units. Furthermore, the test switching unit 50 defines a testing path from a plurality of switch channels according to the control signal provided by the control unit 10, wherein the switch channels can conduct to a plurality of testing paths, and the testing paths are independent and isolated.

For example, if one of the examining unit outputs a testing signal to the control unit 10 based on the testing requirements thereof, the control unit 10 will execute the testing program and control the test switching unit 50 to select a corresponding testing path, therefore the analyzer 40 will measure the examining unit through the selected testing path. Hence, the integrated testing system of the present invention only uses the analyzer 40 to measure various products via the test switching unit 50 switching testing paths, so as to reduce the purchase costs for a number of analyzers and the maintenance costs of those analyzers.

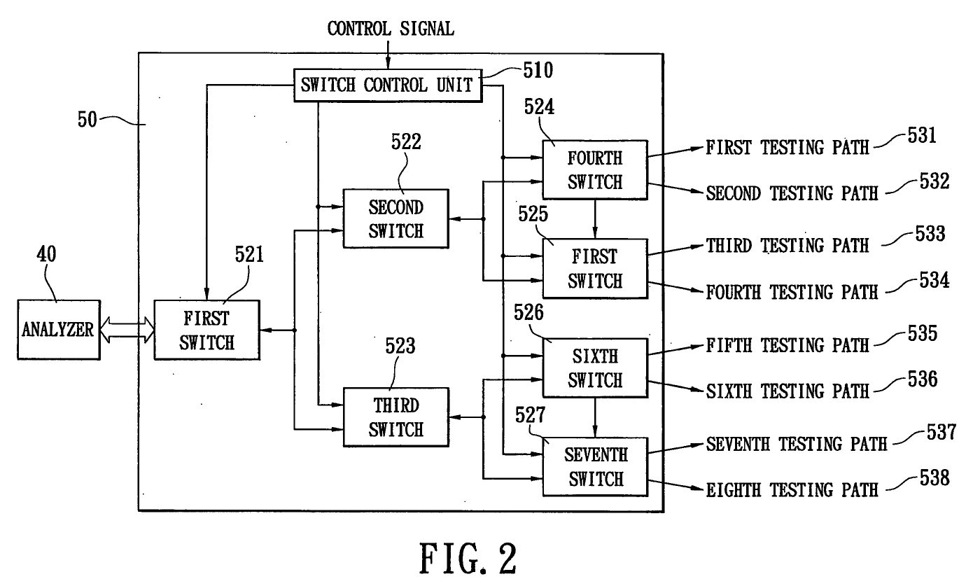

Referring to FIG. 2, a block diagram for the control unit of the present invention of controlling an analyzer and a test switching unit, is shown. The test switching unit 50 includes a switch control unit 510 and a plurality of switches, wherein the number of the switches is based on a users' testing requirements, and the switches operate based on the connections using a tree structure.

In this case, the test switching unit 50 includes seven switches, from the first switch 521 to the seventh switch 527, and each of the switches connects to the switch control unit 510. Accordingly, each of the switches provides two channels for switching, and the output end of the test switching unit 50 provides eight testing paths, from the first testing path 531 to the eighth testing path 538, wherein the testing paths are independent and isolated. Hence, each of the testing paths respectively connects to one examining unit. There are eight examining units in this case.

If the control unit 10 outputs a control signal for controlling the switch control unit 510, the switch control unit 510 will control each of the switches for switching to define a testing path for the test switching unit 50. Next, the analyzer 40 measures the corresponding examining unit based on the defined testing path.

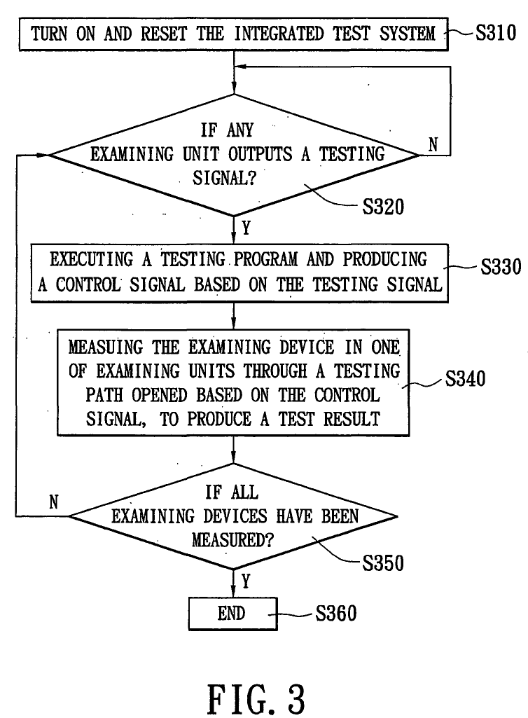

Referring to FIG. 3, a flowchart of the integrated testing method of the present invention is shown. First, after turning on the integrated testing system, all elements of the integrated testing system are reset and are in an initial state (Step S310), wherein the first testing path 531 is selected.

Next, the integrated testing system detects whether one of the examining units has outputted a testing signal based on the testing requirements thereof (Step S320), that is, the integrated testing system detects whether the first examining unit 21 has outputted the testing signal via the first testing path 531. However, if the integrated testing system is in this state, when the first examining unit 21 has not outputted the testing signal, this means that no product has been placed in the first examining device 211 (nor even in any of the other examining devices). The integrated testing system will then wait for a product to be placed in the first examining device 211. If the first examining unit 21 has outputted the testing signal to the control unit 10, the control unit 10 will execute the testing program according to the testing signal produced by a control signal (Step S330)

Hence, the test switching unit 50 initially opens the first testing path 531 from the testing paths according to the control signal, and the analyzer 40 further measures a certain function of the product in the first examining device 211 to obtain a test result (Step S340).

Finally, the integrated testing system determines whether all functions of the product in each of the examining units have been completely measured (Step S350). If all functions of the product in each of the examining units have not been completely measured, the control unit 10 will wait for the next testing signal outputted by one of the examining units. If all functions of the product in each of the examining units have been completely measured, the integrated testing system will close the testing program (Step S360).

In the present invention, each of the examining units with the ability for measuring multiple functions of a product can output a testing signal according to the testing requirements thereof. The integrated testing system can measure the functions of the product in each of the examining units without taking turns to measure each of the functions of a product and each of the examining units. Hence, the present invention can reduce the idle time of the analyzer 40 and the testing period for measuring products.

The advantage of the present invention is that a control unit is used to control the integrated testing system to measure products.

Another advantage of the present invention is that the integrated testing system includes a plurality of examining units for measuring a plurality of products randomly, to reduce the purchasing costs for a number of analyzers and the maintenance costs for those analyzers.

Another advantage of the present invention is that each of the examining units can measure multiple functions of a product.

Another advantage of the present invention is that the switching various testing paths measure various products via a control unit and a test switching unit.

Another advantage of the present invention is that various functions of each of the products can be measured by time-division multiplexing.

Another advantage of the present invention is that interference for measuring wireless and high frequency products is avoided so as to increase the testing accuracy via a test switching unit switching testing paths.

Yet another advantage of the present invention is that the integrated testing system measures products are based on the testing requirements of each of the examining units. Hence, the present invention can reduce the idle period and the average testing period.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. An integrated testing system applied to wireless or high frequency products, comprising:
a plurality of examining units, wherein each of the examining units outputs a testing signal based on the corresponding testing requirements of the examining units;
a control unit receiving the testing signal and based on the testing signal executing a testing program for further outputting a control signal;
a test switching unit switching to the examining unit that outputs the testing signal based on the control signal; and
an analyzer controlled by the control unit connecting to the examining units via the test switching unit for further measuring the examining unit that outputs the testing signal.

2. The integrated testing system according to claim 1, wherein each of the examining units comprises an examining device and an auxiliary testing unit.

3. The integrated testing system according to claim 2, wherein the examining device outputs the testing signal to the control unit via the auxiliary testing unit.

4. The integrated testing system according to claim 2, wherein the auxiliary testing unit is a computer.

5. The integrated testing system according to claim 1, wherein the test switching unit comprises:
at least one switch selecting a testing path between the analyzer and one of the examining units; and
a switch control unit controlling the switches based on the control signal.

6. The integrated testing system according to claim 5, wherein the switches connect to each other in a tree structure.

7. The integrated testing system according to claim 5, wherein each of the switches provides two channels, wherein the channels define the testing path based on the control signal.

8. The integrated testing system according to claim 1, further comprising a instruction transmitter, wherein the examining units connect to the control unit via the instruction transmitter, therefore one of the examining units outputs the testing signal to the control unit.

9. The integrated testing system according to claim 8, wherein the instruction transmitter is a hub.

10. The integrated testing system according to claim 1, wherein the analyzer is an OBT.

11. A test switching unit placed in an integrated testing system for wireless or high frequency products, comprising:
a plurality of switches comprising a plurality of testing paths which are independent and isolated; and
a switch control unit connecting to the switches so as to control the switches.

12. The test switching unit according to claim 11, wherein the switches connect to each other in a tree structure.

13. The test switching unit according to claim 11, wherein each of the switches provides two channels, wherein the channels define the testing path based on the control signal.

14. An integrated testing method, comprising:
determining whether an examining unit in an integrated testing system outputs a testing signal;
executing a testing program so as to produce a control signal according to the testing signal;
selecting one of a plurality of testing paths for an analyzer according to the control signal; and
measuring a product in the examining unit so as to producing a test result according to the testing program and the selected testing path.

15. The integrated testing method according to claim 14, wherein the examining unit outputs the testing signal so as to produce the control signal according to the testing requirements of the examining unit.

16. The integrated testing method according to claim 15, wherein the analyzer measures multiple functions of the product according to the testing requirements of the examining unit.

17. The integrated testing method according to claim 14, wherein the examining unit transmits the testing signal to a control unit to execute the testing program and produce the control signal.

18. The integrated testing method according to claim 17, wherein the examining unit transmits the testing signal to the control unit via the network.

19. The integrated testing method according to claim 14, wherein the integrated testing method is applied to wireless and high frequency products.
